(19) United States
(12) Patent Application Publication
(10) Pub. No.: US 2023/0136819 A1
(43) Pub. Date: May 4, 2023

(54) CONTROL OF WAFER BOW DURING INTEGRATED CIRCUIT PROCESSING

(71) Applicant: Lam Research Corporation, Fremont, CA (US)

(72) Inventors: David W. Porter, Sherwood, OR (US); Fayaz A. Shaikh, Lake Oswego, OR (US); Katsunori Yoshizawa, Tigard, OR (US)

(21) Appl. No.: 17/905,321

(22) PCT Filed: Mar. 1, 2021
(86) PCT No.: PCT/US2021/020284

§ 371 Date: Aug. 30, 2022

Related U.S. Application Data
(60) Provisional application No. 62/985,438, filed on Mar. 5, 2020.

(51) Int. Cl. H01L 21/66; H01L 21/67; H01L 21/02

(52) U.S. Cl. CPC H01L 22/12; H01L 21/67155; H01L 21/67288; H01L 21/02164; H01L 21/0217

(57) ABSTRACT

A method of controlling wafer bow in an integrated circuit fabrication process may include characterizing the wafer bow in response to performing one or more first fabrication processes to an active side of an integrated circuit wafer. Determining one or more second fabrication processes, to be applied to a back side of the integrated circuit wafer, to bring the wafer bow to below a predetermined threshold based on the one or more first fabrication processes the method may additionally include performing the one or more second fabrication processes on the back side of the integrated circuit wafer.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Background and contextual descriptions contained herein are provided solely for the purpose of generally presenting the context of the disclosure. Much of this disclosure presents work of the inventors, and simply because such work is described in the background section or presented as context elsewhere herein does not mean that such work is admitted to be prior art.

Fabrication of semiconductor wafers utilized to form integrated circuits may include numerous and diverse processing steps. In certain processing steps, which may occur after various materials are deposited onto a semiconductor wafer, material may be etched away, so as to allow additional materials, such as metals, to be deposited. Such deposition may involve formation of conductive traces, transistor gates, vias, circuit elements, and so forth. However, in at least some instances, deposited materials may give rise to tensile stresses at a surface of a semiconductor wafer. Such tensile stress can give rise to bowing of a semiconductor wafer, in which the wafer assumes a concave shape or a convex shape. Responsive to the wafer having a concave shape, for example, subsequent semiconductor processes, such as photolithography, masking, singulation, may become problematic. In some instances, excessive bowing of a semiconductor wafer may necessitate scrapping an entire wafer. Accordingly, techniques to increase control over bowing of a semiconductor wafer continues to be an active area of investigation.

### SUMMARY

General aspects of the claims include a method of performing a process on a wafer, where the method includes: (a) determining how wafer bow changes with temperature, wherein the wafer bow is at least partially caused by one or more processes performed on a front side of a wafer; (b) using information about how the determined wafer bow changes with temperature to determine properties of a back side treatment of wafers, which back side treatment counteracts the wafer bow; (c) applying the back side treatment identified in (b) to an incoming wafer; and (d) performing the one or more processes on the front side of the incoming wafer, whereby the back side treatment applied in (c) at least partially prevents the incoming wafer from bowing in response to the one or more processes.

In the above-described method, the one or more processes performed on the front side of the wafer can comprise a deposition process. The one or more processes performed on the front side of the wafer can comprise multilayer stack deposition. The one or more processes performed on the front side of the wafer can comprise oxide/nitride (ONON) deposition. The one or more processes performed on the front side of the wafer can comprise an etching process. Determining how wafer bow changes with temperature can comprise measuring wafer bow of a test wafer at multiple different temperatures while the temperature of the test wafer increases. Determining how wafer bow changes with temperature can comprise measuring wafer bow of a test wafer at multiple different temperatures while the temperature of the test wafer decreases. Determining how wafer bow changes with temperature can comprise determining a hysteresis of wafer bow in response to at least one cycle of increasing temperature and decreasing temperature. Determining how wafer bow changes with temperature can comprise measuring wafer bow of a test wafer at multiple different temperatures within a range of temperatures experienced by the incoming wafer during the one or more processes on the front side of the incoming wafer. The back side treatment can comprise applying one or more layers to the back side of the incoming wafer. Using the information about how the determined wafer bow changes with temperature to determine properties of a back side treatment of the wafer can comprise obtaining temperature versus bow information for test wafers having one or more deposited layers on the back sides of the test wafers. In certain aspects, a first test wafer can have a layer of a first material on its back side and a second test wafer can have a deposited layer of a second material on its back side. Using the information about how the determined wafer bow changes with temperature to determine properties of a back side treatment of the wafer further can comprise determining a back side treatment that includes: depositing a first layer of the first material to a first thickness on the wafer's back side, and depositing a second layer of the second material to a second thickness on the wafer's back side.

In one or more additional aspects, an apparatus for controlling wafer bow during integrated circuit processing is provided, where the apparatus includes: one or more process stations of a multi-station fabrication chamber, the one or more process stations being configured to receive a corresponding number of semiconductor wafers having undergone a fabrication process at a back side of each wafer, the one or more process stations being additionally configured to perform a fabrication process to an active side of each wafer, the one or more process stations being additionally configured to cooperate with each received semiconductor wafer to maintain wafer bow to a value below a threshold level during the fabrication process performed to the active side of each wafer.

In the above-described apparatus, the fabrication process performed to the active side of each wafer can involve elevating the temperature of the wafer followed by reducing the temperature of the wafer. The fabrication process performed to the active side of each wafer can comprise material deposition. The fabrication process performed to the active side of each wafer can comprise removal of material from the wafer. In an aspect, the threshold level can correspond to about 100 μm and each wafer can have a diameter of about 300 mm. In an aspect, the threshold level can correspond to about 75 μm and each wafer can have a diameter of about 300 mm. The multi-station fabrication chamber can comprise 4 process stations. The fabrication process at the back side of each wafer can comprise depositing silicon oxide and/or silicon nitride layers.

In one or more additional aspects, a method of controlling wafer bow in an integrated circuit fabrication process is provided, the method including: characterizing the wafer bow in response to performing one or more active fabrication processes to an active side of an integrated circuit wafer; determining one or more second fabrication processes, to be applied to a back side of the integrated circuit wafer, to bring the wafer bow to below a predetermined threshold based on the one or more active fabrication processes; and performing the one or more second fabrication processes on the back side of the integrated circuit wafer.

In the above-described method, the one or more active fabrication processes performed to the active side of the integrated circuit wafer can comprise elevating the temperature of the integrated circuit wafer. The one or more active fabrication processes performed to the active side of the integrated circuit wafer can comprise depositing a material on the active side of the integrated circuit wafer. The material deposited on the active side of the integrated circuit wafer can comprise silicon nitride. The material deposited on the active side of the integrated circuit wafer can comprise silicon oxide. The one or more active fabrication processes performed to the active side of the integrated circuit wafer can comprise removing a material from the active side of the integrated circuit wafer. Performing the one or more second fabrication processes on the back side of the integrated circuit wafer can result in decreasing the wafer bow to an amount below 100 μm when the wafer has a diameter of about 300 mm. Performing the one or more second fabrication processes on the back side of the integrated circuit wafer can result in decreasing the wafer bow to an amount below about 75 μm when the wafer has a diameter of about 300 mm. Performing the one or more second fabrication processes on the back side of the integrated circuit wafer can comprise depositing a silicon oxide layer, a silicon nitride layer, or both a silicon oxide and a silicon nitride layer at the back side

### BRIEF DESCRIPTION OF THE DRAWINGS

FIG. 1 is a flowchart that illustrates example operations for reducing substrate bow, according to an embodiment.

FIG. 2A is a diagram showing bowing of a semiconductor wafer which may result during processing, according to an embodiment.

FIGS. 2B-2D are graphs showing temperature-related hysteresis of candidate materials deposited on the substrate, according to an embodiment.

FIG. 3 is a diagram showing wafer bowing of oxide/nitride layers, according to an embodiment.

FIG. 4 is a diagram showing an estimate of wafer bowing for a oxide/nitride layers, silicon oxide+ silicon nitride and combined layers, according to an embodiment.

FIG. 5 is a diagram showing a shift in bowing of an active side of a semiconductor wafer responsive to various layer types, according to an embodiment.

FIG. 6 shows a substrate processing apparatus for depositing films on semiconductor substrates utilizing any number of processes.

FIG. 7 is a block diagram showing various components of a system utilized to perform a semiconductor fabrication process, according to an embodiment.

### DETAILED DESCRIPTION

In this application, the terms “semiconductor wafer,” “wafer,” “substrate,” “wafer substrate,” and “partially fabricated integrated circuit” are used interchangeably. Further, the term “partially fabricated integrated circuit” can refer to a silicon wafer during any of many stages of integrated circuit fabrication thereon. A wafer or substrate used in the semiconductor device industry typically has a diameter of about 200 or about 300 mm, though the industry is moving toward adoption of substrates having a diameter of about 450 mm. The description herein uses the terms “front side” or “active side” may refer to a first side of a semiconductor wafer, while the term “back side” may refer to the reverse side of a semiconductor wafer. It is understood that the active or front side is where most deposition and processing occurs, and where the semiconductor devices themselves are fabricated. The back side is the opposite side of the wafer, which typically experiences minimal or no processing during fabrication.

The flow rates and power levels provided herein are appropriate for processing on 300 mm substrate, unless otherwise specified. It should be noted that these flows and power levels may be adjusted as necessary for substrates of other sizes. The following detailed description assumes that certain implementations may occur on a wafer. However, the implementations are not so limited. The work piece may be of various shapes, sizes, and materials. In addition to semiconductor wafers, other work pieces that may take advantage of at least certain various implementations include various articles such as printed circuit boards and the like.

In the following description, numerous specific details are set forth in order to provide a thorough understanding of certain implementations. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

As discussed above, deposition of materials on the active side of a wafer substrate can lead to stress and bowing problems in the wafer. These problems are especially likely to occur where large stacks of materials are deposited, for example in the context of 3D-NAND devices. Wafer bowing can cause complications in subsequent processing steps. For instance, the wafer may fail to chuck correctly if the bowing is too great. Further, certain processing steps (e.g., photolithography) are very precise and produce poor results if the wafer is not substantially flat when processing.

One technique for combating the stress and bowing issues is to deposit a film on the back side of the wafer. The back side film counteracts the stress from the active side deposition to result in a neutral stress (or substantially neutral stress, e.g., less than about +/−150 MPa) wafer that shows no bowing (or at least bowing of less than a predetermined amount such as 150 μm, 100 μm, 75 μm, 60 μm). If the film deposited on the active side is tensile, then the back side film should also be tensile to balance out the overall stress. Likewise, if the active side film is compressive, then the back side film should also be compressive. The back side film may be deposited through various reaction mechanisms (e.g., chemical vapor deposition (CVD), plasma enhanced chemical vapor deposition (PECVD), atomic layer deposition (ALD), plasma enhanced atomic layer deposition (PEALD), low pressure chemical vapor deposition (LPCVD), etc.). In various cases, plasma enhanced chemical vapor deposition is used due to the high deposition rate achieved in this type of reaction.

Certain deposition parameters can be tuned to produce a back side film having a desired stress level. One of these deposition parameters is the thickness of the deposited back side film. Thicker films induce more stress in the wafer, while thinner films (of the same composition and deposited under the same conditions) induce less stress in the wafer. Therefore, in order to minimize the amount of material consumed in forming the back side layer, this layer may be deposited relatively thinly under conditions that promote formation of a highly-stressed film. In other implementations, a back side film providing a desired stress level may be brought about by depositing layers of silicon oxide and/or silicon nitride, each of predetermined thicknesses, so as to achieve a desired tensile stress or a desired compressive stress. In addition to layers of predetermined thicknesses, the number of silicon oxide and/or silicon nitride layers may be adjusted to a desired tensile stress or a desired compressive stress. In certain embodiments, a number of silicon oxide and/or silicon nitride layers may be tailored to counteract tensile or compressive stress that is brought about at the active side of a semiconductor wafer.

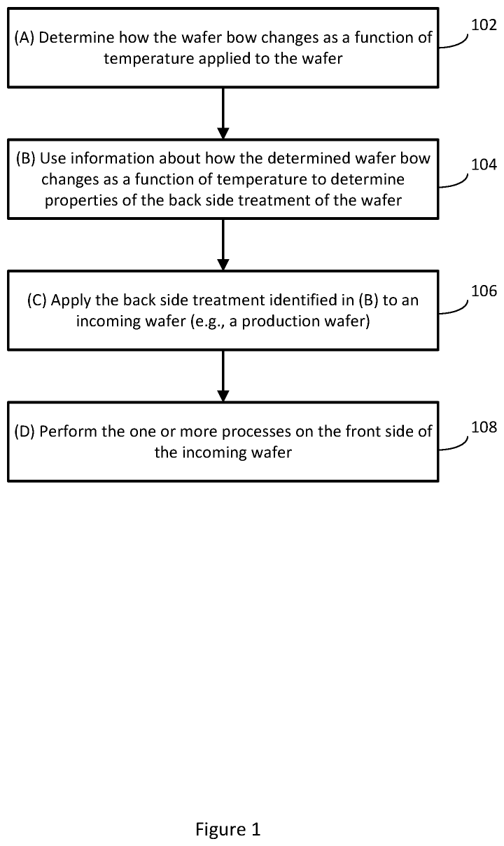

FIG. 1 shows a flowchart that illustrates an example sequence of operations to reduce substrate bow.

At 102, operation (A) to determine how wafer bow changes as a function of temperature applied to the wafer can be performed. To determine or estimate wafer bow, and particularly wafer bow as a function of temperature, various metrology and/or analytical techniques may be employed. In certain embodiments, to determine wafer bow, a test wafer may be employed. The test wafer may have some front or active side processing performed and the bow reflects internal stresses caused by that front side processing. In some embodiments, a goal of the process is to determine back side processing that compensates for the bowing resulting from internal stresses caused by one or more front side processes. Therefore, the test wafer may be fully or partially processed in accordance with the front side processing that is to be compensated for. As an example, a test wafer may have a fully or partially deposited stack including alternating layers of silicon oxide and silicon nitride (ONON) on the front or active side of a semiconductor wafer.

Certain front side processes produce temperature variations on the wafer. For example, some processes are performed at elevated temperatures (e.g., about 300° C. or higher). A production wafer may be stored at room temperature (e.g., in a front-opening universal pod or FOUP) waiting in a queue of wafers to be processed. When the wafer is delivered to a process chamber where the elevated temperature process is to be performed, the wafer is heated. After processing is complete, the wafer may be cooled by, for example, removal from the process chamber. This heating-processing-cooling process may introduce a sequence of bowing that culminates in bow to the wafer that has been fully processed.

To design a back side treatment (e.g., depositing one or more back layers) that accounts for the bow variations experienced by production wafers during a particular process or group of processes that involve temperature variations, the test wafer may be evaluated at multiple temperatures within or overlapping with the range of temperatures experienced by a production wafer in processes that introduce bow.

In certain embodiments, the test wafer is exposed to at least two or more different temperatures within or overlapping with the range of temperatures experienced by a production wafer in processes that introduce bow. In certain embodiments, the test wafer is exposed to a range of temperatures that cover less than about 50% of the range of temperatures experienced by a production wafer in processes that introduce bow. In certain embodiments, the test wafer is exposed to a range of temperatures that cover at least about 50% of the range of temperatures experienced by a production wafer in processes that introduce bow. In certain embodiments, the test wafer is exposed to a range of temperatures that cover about 80% of the range of temperatures experienced by a production wafer in processes that introduce bow. In certain embodiments, the test wafer is exposed to a range of temperatures that include at least the range about 50° C. to about 400° C. In certain embodiments, the test wafer is exposed to a range of temperatures that include at least the range about 30° C. to about 500° C.

In certain embodiments, the test wafer is exposed to a sequence of two more temperatures of increasing temperature, and the same test wafer is exposed to a sequence of two more temperatures of decreasing temperature. In this way, bow versus temperature hysteresis may be measured.

Wafer bow may be measured by various techniques. One example is low coherence laser interferometry utilizing a Michelson interferometer with a low coherence light source such as one or more components of the 413 Series Thickness and Total Variation (TTV) mapping system sold by the Frontier Semiconductor Company located at 165 Topaz St., Milpitas, Calif. 95035. Such equipment can measure substrate thickness, warp, and TTV, with or without Tape, for Wafer Backgrind and Etch Thinning processes. In certain embodiments, bow is not measured directly or a surrogate for bow is measured. For example, the internal stress, which gives rise to bow and results from front side processing, is measured.

At 104, operation (B) that uses information about how the determined wafer bow changes as a function of temperature to determine properties of the back side treatment can be performed. The bow versus temperature response of a wafer contains information that allows design of a back side treatment that counteracts the wafer bow over a range of temperatures associated with front side processing.

Various back side processes may be employed. Examples include deposition of one or more layers, etching (wet or dry), implantation/doping, and exposure to plasma. The process may identify any one or more of these types of back side processes to counteract temperature-dependent bowing in one or more front side processes.

In various embodiments, determining a back side treatment to counteract bowing employs temperature-dependent information about one or more optional back side treatments. For example, the determination may employ data about how a test wafer with a layer of one material (e.g., silicon oxide) bows with different temperatures. In some cases, the determination may employ data about how two different test wafers each with a different layer of material (e.g., silicon oxide and silicon nitride) bow with different temperatures. In another example, the determination may employ data about how a test wafer with some material etched away (or exposed to plasma) bows with different temperatures. In another example, a first test wafer may include a first material (e.g., silicon nitride) on its back side and a second wafer may include a deposited layer of a second material (e.g., silicon oxide) on its back side.

In certain embodiments, one or more test wafers having the optional back side treatments are exposed to a range of temperatures that substantially tracks the range of temperatures experienced by a production wafer in processes that introduce bow (i.e., the processes that the back side processing will compensate for). In certain embodiments, one or more test wafers having the optional back side treatments are exposed to a range of temperatures that substantially tracks the range of temperatures that a different test wafer is exposed for purposes of generating the bow versus temperature information for front side processing (e.g., operation (A) discussed above).

Various analytical techniques may be employed to determine a back side treatment to be applied to production wafers to counteract bowing caused by the one or more processes performed on a front side of a wafer. For example, a technique may compare the bow caused by the one or more processes at various temperatures against the bow caused by each of multiple optional back side processes at the various temperatures. In this way, a composite back side process can be determined that accounts for bowing over a range of temperatures. In certain embodiments, this temperature dependent comparison can be accomplished implicitly, as by a machine learning technique, for example.

It should be apparent that, in some embodiments, a determined back side treatment is a composite of two or more optional/unitary back side processes. In one example, the back side treatment includes depositing two or more layers on top of one another. In certain embodiments, these layers are different materials.

At 106, operation (C) to apply the back side treatment identified in (B) to an incoming wafer (e.g., a production wafer) can be performed. In certain embodiments, the same back side treatment is performed on a batch of wafers or multiple batches of wafers, without re-determining an appropriately compensating back side treatment. In some embodiments, the same back side treatment is performed on all wafers subject to a defined process (or process sequence) for which the back side treatment was determined. The back side treatment applied to production wafers at least partially prevent those wafers from bowing in response to the front side processes.

At 108, operation (D) to perform the one or more processes on the front side of the incoming wafer can be performed.

When a front side process parameter changes (for a production process), a compensating back side treatment may be re-determined via operations (A) and (B) as discussed above. In this case, at least the bow versus temperature information for the new or modified front side processing is generated. The resulting new information is applied in operation (B) to determine a new back side treatment.

In some examples, the back side treatment is determined using (i) bow metrology on test wafers that have undergone front side processing corresponding to a production process, (ii) bow metrology on different test wafers that have undergone different optional back side treatments that might counteract bow induced by the front side processing, (iii) and an analytical technique that compares temperature-dependent bowing obtained via (i) and (ii). This process may be conducted infrequently, for example, whenever a front side process parameter changes, a new process chamber is used, or some other change to the production process occurs.

In certain embodiments, both active side and back side processing may be achieved utilizing one or more RF signals, which may operate to generate a plasma, which may bring about or enhance particular wafer fabrication processes. Active side and back side processing may be affected by the RF power coupled to a fabrication chamber, the frequency of the RF signal that brings about formation of the plasma, the exposure time of the plasma, temperature of the substrate and reaction chamber, pressure within the reaction chamber, flow of inert gas, composition of reactants, etc. as the high frequency (HF, e.g., about 13.5 MHz, or about 27.0 MHz, for example) component of the RF power used to generate the plasma increases, the tensile stress response of the film may also increase, while the compressive stress response shows substantially no change. Example HF RF powers may range between about 0-2500 Watts per station of a multi-station fabrication chamber. As the low frequency (LF, e.g., about 356 kHz, about 400 kHz, etc.) component of the RF power used to generate the plasma increases, the tensile stress response of the film may decrease, and the compressive stress response of the film may increase. Example LF RF frequencies may range between about 200 KHz-4 MHz. Example LF powers may range between about 0-2500 Watts per station. In various cases, the LF+HF powers together may range between about 0-2500 Watts per station. As the plasma exposure time and/or duty cycle increases, the stress response may change as indicated above depending on the frequency used and the type of film stress involved. Example RF exposure times depend on the type of deposition occurring. For instance, plasma enhanced chemical vapor deposition involves exposure to plasma for relatively long periods of time, while plasma enhanced atomic layer deposition involves repeated exposure to plasma for much shorter periods of time. As the temperature of the substrate during deposition increases, both the tensile and compressive stress responses of the film increase. Example substrate and chamber temperatures also depend on the deposition process, but may be between about 25° C. to about 650° C. As the pressure in the reaction chamber during deposition increases, the tensile stress response of the film increases, and the compressive stress response of the film may decrease. Example chamber pressures range between about 1-4 Torr. As the inert gas flow delivered to the reaction chamber during deposition increases, the tensile stress response shows no change, and the compressive stress response increases. Example flow rates for inert gas may be between about 100-5000 sccm. Another parameter that may affect film stress is the electrode spacing. The electrode spacing is important because it affects the E-field on the wafer, which can affect on-film density. As the electrode spacing increases, there is no response in the tensile stress response, and the compressive stress response decreases. Example electrode spacing may be between about 5-30 mm. Other reaction parameters related to back side deposition will be further discussed below.

Another variable that can affect the degree of stress in a film is the hydrogen content of the film which can be controlled by the flow of NH₃ or other hydrogen-containing reactant. One or more of the variables discussed above may also directly or indirectly affect the hydrogen content of the film.

As mentioned, stacks of deposited materials are especially likely to result in wafer stress and bowing. One example stack that may cause these problems is a stack having alternating layers of oxide and nitride (e.g., silicon oxide/silicon nitride/silicon oxide/silicon nitride (ONON), etc.). Another example stack likely to result in bowing includes alternating layers of oxide and polysilicon (e.g., silicon oxide/polysilicon/silicon oxide/polysilicon, etc.). Other examples of stack materials that may be problematic include, but are not limited to, tungsten and titanium nitride. The materials in the stacks may be deposited through chemical vapor deposition techniques such as plasma enhanced chemical vapor deposition (PECVD), low pressure chemical vapor deposition (LPCVD), metal organic chemical vapor deposition (MOCVD), atomic layer deposition (ALD), plasma enhanced atomic layer deposition (PEALD), or through direct metal deposition (DMD), etc. These examples are not intended to be limiting. Certain disclosed embodiments may be useful whenever wafer stress and/or bowing are induced due to material present on the active side of the wafer.

The active side stacks may be deposited to any number of layers and thicknesses. In a typical example, the stack includes between about 32-72 layers, and has a total thickness between about 2-4 μm. The stress induced in the wafer by the stack may be between about −500 MPa to about +500 MPa, resulting in a bow that is frequently between about 200-400 μm (for a 300 mm wafer), and even greater in some cases.

The material deposited on the back side of the wafer may be a dielectric material in various embodiments. In particular implementations, an oxide and/or nitride (e.g., silicon oxide and/or silicon nitride) is used. However, in other implementations, silicon-containing reactants that may be used include, but are not limited to, silanes, halosilanes, and aminosilanes. A silane contains hydrogen and/or carbon groups, but does not contain a halogen. Examples of silanes are silane (SiH₄), disilane (Si₂H₆), and organo silanes such as methyl silane, ethyl silane, isopropylsilane, t-butylsilane, dimethylsilane, diethyl silane, di-t-butylsilane, allylsilane, sec-butylsilane, t-hexylsilane, isoamylsilane, t-butyldisilane, di-t-butyldisilane, and the like. A halosilane contains at least one halogen group and may or may not contain hydrogens and/or carbon groups. Examples of halosilanes are iodosilanes, bromosilanes, chlorosilanes and fluorosilanes. Although halosilanes, particularly fluorosilanes, may form reactive halide species that can etch silicon materials, in certain embodiments described herein, the silicon-containing reactant is not present when a plasma is struck. Specific chlorosilanes are tetrachlorosilane (SiCl₄), trichlorosilane (HSiCl₃), dichlorosilane (H₂SiCl₂), monochlorosilane (ClSiH₃), chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, t-hexyldimethylchlorosilane, and the like. An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHC1-(N(CH₃)₂)₂, (Si(CH₃)₂NH)₃ and the like. A further example of an aminosilane is trisilylamine (N(SiH₃)₃). Other potential silicon-containing reactants include tetraethyl orthosilicate (TEOS), and cyclic and non-cyclic TEOS variants such as tetramethoxysilane (TMOS), fluorotriethoxysilane (FTES), Trimethylsilane (TMS), octamethyltetracyclosiloxane (OMCTS), tetramethylcyclotetrasiloxane (TMCTSO), dimethyldimethoxysilane (DMDS), hexamethyldisilazane (HMDS), hexamethyldisiloxane (HMDSO), hexamethylcyclotrisiloxane (HMCTSO), dimethyldiethoxysilane (DMDEOS), methyltrimethoxysilane (MTMOS), tetramethyldisiloxane (TMDSO), divinyltetramethyldisiloxane (VSI2), methyltriethoxysilane (MTEOS), dimethyltetramethoxydisiloxane (DMTMODSO), ethyltriethoxysilane (ETEOS), ethyltrimethoxysilane (ETMOS), hexamethoxydisilane (HMODS), bis(triehtoxysilyl)ethane (BTEOSE), bis(trimethoxysilyl)ethane (BTMOSE), dimethylethoxysilane (DMEOS), tetraethoxydimethyldisiloxane (TEODMDSO), tetrakis(trimehtylsiloxy)silane (TTMSOS), tetramethyldiethoxydisiloxane (TMDEODSO), triethoxysilane (TIEOS), trimethoxysilane (TIMEOS), or tetrapropoxysilane (TPOS).

Example nitrogen-containing reactants include, but are not limited to, ammonia, hydrazine, amines (e.g., amines bearing carbon) such as methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants.

Examples of oxygen-containing co-reactants include oxygen, ozone, nitrous oxide, carbon monoxide, nitric oxide, nitrogen dioxide, sulfur oxide, sulfur dioxide, oxygen-containing hydrocarbons (CₓH_{y} O_{z}), water, mixtures thereof, etc.

The flow rate of these reactants may depend on the type of reaction through which the back side layer is deposited. Where CVD/PECVD are used to deposit the back side layer, the flow rate of the silicon-containing reactant may be between about 0.5-10 mL/min (before atomization), for example between about 0.5-5 mL/min. The flow rate of a nitrogen-containing reactant, oxygen-containing reactant, or other co-reactant may be between about 3-25 SLM, for example between about 3-10 SLM.

The optimal thickness of the back side layer may depend on the amount of stress induced by the deposition on the active side of the wafer, as well as the conditions under which the back side layer is deposited. The back side layer may be deposited to a thickness at which the stress in the wafer becomes negligible (e.g., less than about 150 MPa). In these or other embodiments, the back side layer may be deposited to a thickness at which the wafer bow becomes negligible (e.g., less than about 150 μm of bow). In some cases, this corresponds to a back side layer thickness between about 0.1-2 μm, for example between about 0.3-2 μm, or between about 0.1-1 μm, or between about 0.3-1 μm. Where silicon nitride is used to form the back side layer, a film having a thickness of about 0.3 μm is sufficient to mitigate a bow of about 50-200 μm. As mentioned above, a higher stress back side layer may be used to reduce the required thickness of the layer. This helps conserve materials and reduce costs.

Thus, in certain other cases the back side deposition is carried out in an apparatus that is specifically designed to deposit on the back side of a wafer, even when the wafer is in its right-side-up orientation (i.e., with the active side of the wafer pointing upwards). Such an approach eliminates the need to form a protective layer on the active side of the wafer before the back side deposition occurs. In some embodiments, a deposition apparatus may be used to deposit on both the active and back side of a wafer, without flipping the wafer over (i.e., the deposition apparatus can perform both active side deposition and back side deposition without altering the orientation of the wafer). Where this is the case, various components of the apparatus may be included at both the top and bottom of the reaction chamber (e.g., showerhead or other inlets, outlets, plates or other components for providing a thin gap between the current non-plating face of the wafer and the plate, electrical connections, etc.).

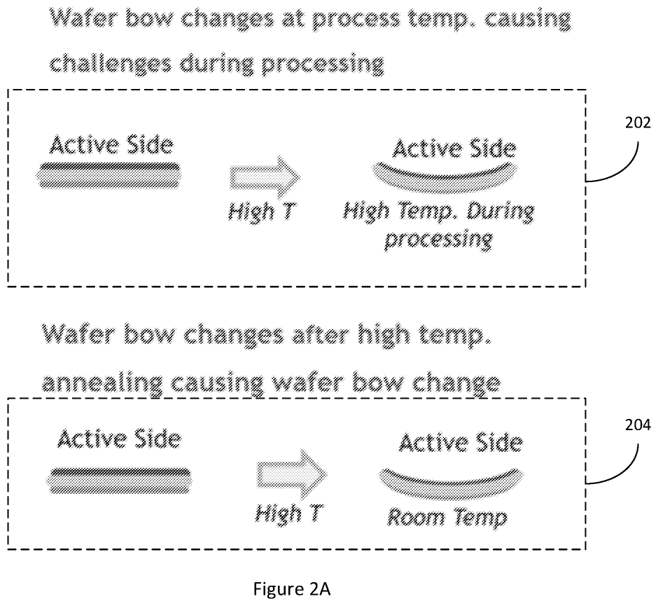

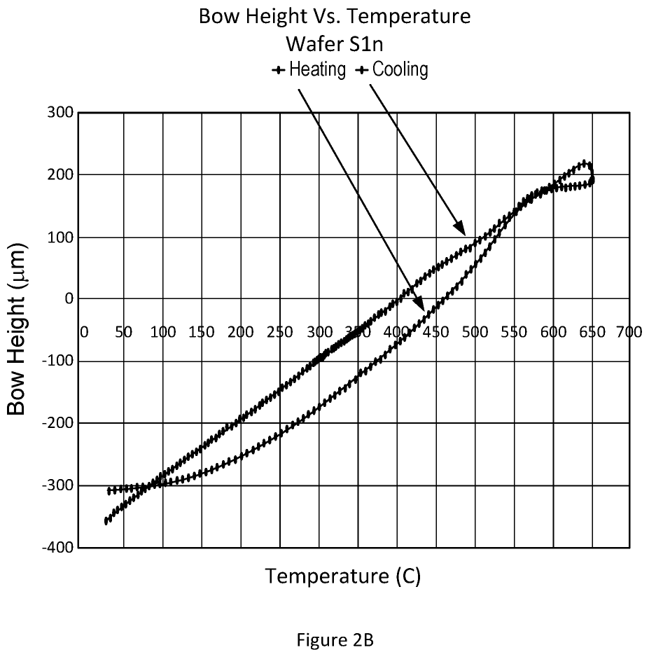

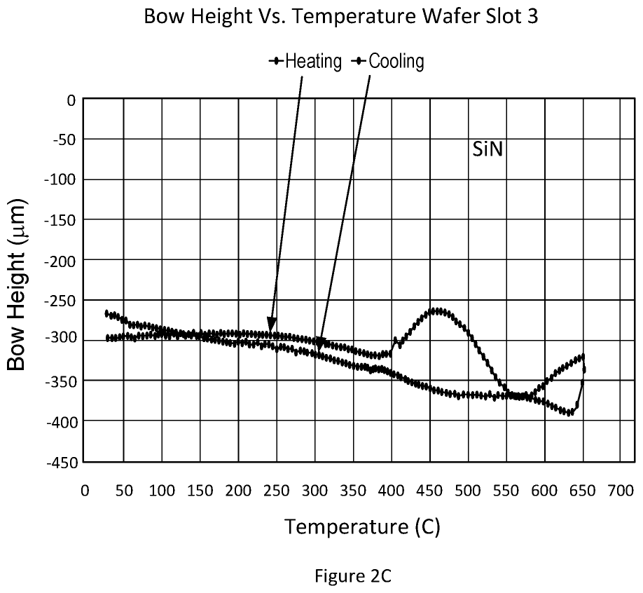

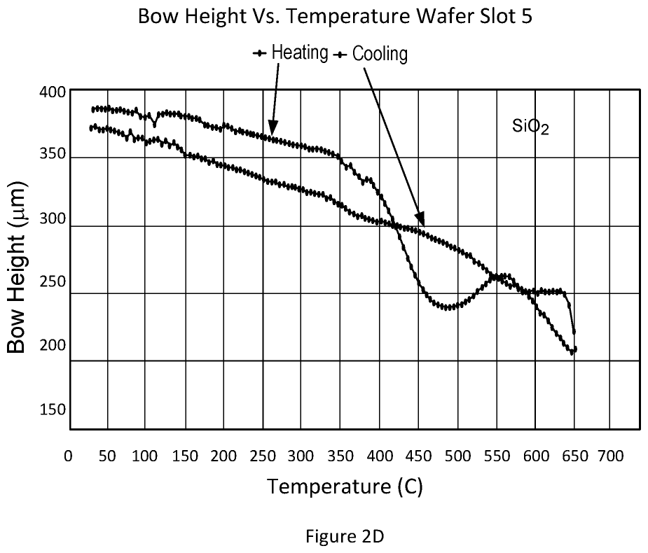

FIG. 2A is a diagram showing bowing of a semiconductor wafer which may result during processing, according to an embodiment.

As shown in 202 of FIG. 2A, the active side of a semiconductor wafer may assume a shape responsive to exposure to elevated temperatures during processing. Such elevated temperatures may include annealing temperatures, for example, encountered during deposition processes and/or etching processes. As shown in 204 of FIG. 2A, the results of a hysteresis phenomenon, in which a semiconductor wafer at room temperature may remain bowed after having been exposed to an elevated temperature, is illustrated. Accordingly, as shown, even at room temperature, tensile stress at an active side of a semiconductor wafer may draw the end portions of the wafer toward a center portion of the wafer, thereby forming a bow-shaped wafer.

FIG. 2B shows a graph of temperature-related hysteresis of a candidate material (referred to as “S1n”) deposited on a substrate, according to an embodiment. In the graph of FIG. 2B, the vertical axis corresponds to bow height (in microns), wherein a negative value for bow height corresponds to a convex-shaped semiconductor wafer, and wherein a positive value for bow height corresponds to a concave-shaped semiconductor wafer. The horizontal axis of FIG. 2B corresponds to a temperature, which may include temperatures from about room temperature (about 30° C.) to a relatively high temperature, such as a temperature of about 650° C. A temperature of about 650° C. may embrace temperatures likely to be encountered during one or more semiconductor processes. As shown in FIG. 2B, bow height encountered during heating of a semiconductor substrate may be slightly less, such as between about 0 and about 50 μm, than the bow height encountered during wafer cooling. Also shown in FIG. 2B, after heating and cooling, such as upon returning to room temperature (e.g., about 30° C.), a bow height may differ by about 50 μm.

FIG. 2C shows a graph of temperature-related hysteresis of a candidate material (e.g. silicon nitride or SiN) deposited on a substrate, according to an embodiment.

As shown in FIG. 2C, as a semiconductor wafer comprising one or more silicon nitride layers is brought from about 30° C. (e.g., room temperature) to a temperature of about 650° C., the bow height of silicon nitride illustrates a hysteresis. Hysteresis between heating and cooling of a semiconductor wafer comprising one or more silicon nitride layers appears especially pronounced at a temperature range of between about 400° C. and about 525° C. Further, it should be noted that since the bow height of FIG. 2C comprises negative values, the semiconductor wafer would exhibit a convex shape.

FIG. 2D shows a graph of temperature-related hysteresis of a candidate material (e.g. silken oxide or SiO₂) deposited on a substrate, according to an embodiment.

As shown in FIG. 2D, as a semiconductor wafer comprising one or more silicon oxide layers is brought from about 30.0° C. (e.g., room temperature) to a temperature of about 425° C., the measured bow height is greater than the bow height measured during a decrease in temperature, such as from about 425° C. to about 30° C. During heating between about 425° C. and about 550° C., the bow height measured is slightly less than the bow height measured during cooling, such as from about 550° C. to 425° C. In addition, it should be noted that the bow height of FIG. 2D is shown as comprising positive values, which indicates a concave shape.

Accordingly, it may be appreciated from FIGS. 2C and 2D, that via a use of layers of silicon nitride (SiN), which may bring about a negative bow height (e.g., corresponding to a convex-shaped bow), versus layers of silicon oxide (SiO₂), which may bring about a positive bow height (e.g., corresponding to a concave-shaped bow) bowing of a semiconductor wafer can be adjusted to achieve a substantially neutral shape (e.g., substantially flat) that does not include a significant convex or concave bow shape. Further, when an active layer is populated with devices that bring about positive or negative bowing of a semiconductor wafer, material composition of the back side of the semiconductor wafer can be adjusted utilizing appropriate numbers and thicknesses of SiN and/or SiO₂.

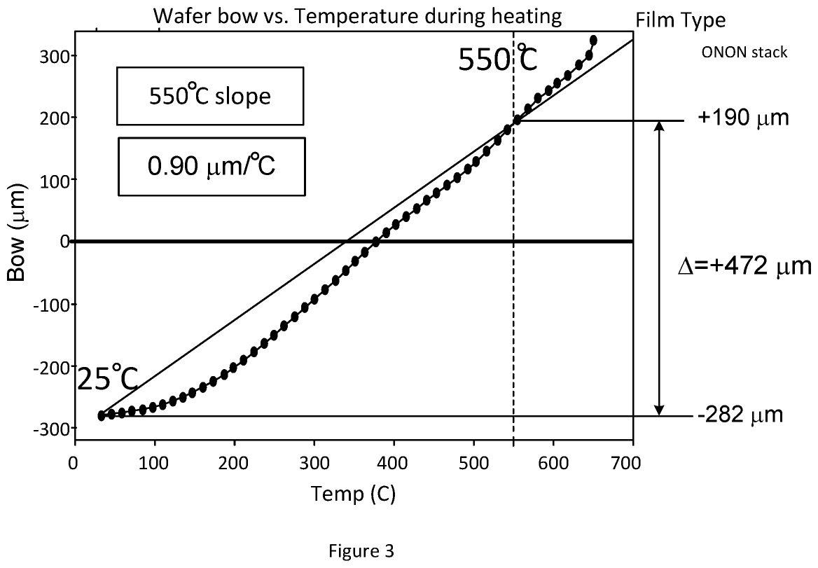

FIG. 3 is a diagram showing wafer bowing of oxide/nitride (ONON) layers, according to an embodiment. It may be appreciated that FIG. 3 exhibits both negative bowing (e.g., having a convex shape) as well as positive bowing (e.g., having a concave shape) as a function of temperature. In the example illustrated at FIG. 3, at a temperature from about 25° C. to about 350° C., a semiconductor substrate having one or more oxide/nitride layers may assume a convex shape, while at temperatures from about 350° C. to about 650° C., the semiconductor substrate may assume a concave shape.

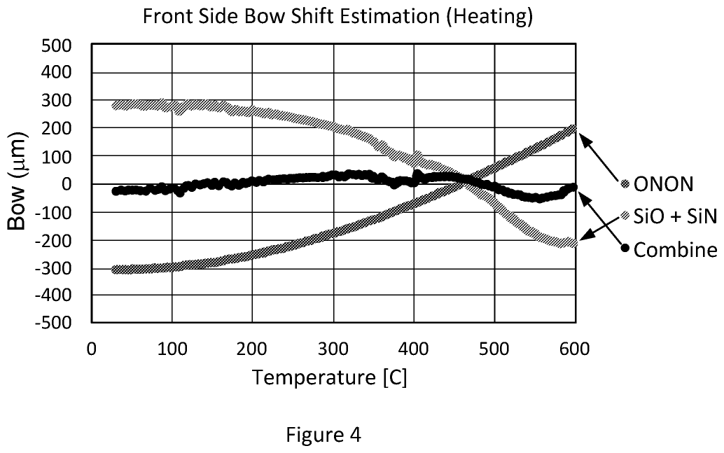

FIG. 4 is a diagram showing an estimate of wafer bowing for oxide/nitride layers (ONON), silicon oxide+ silicon nitride, and combined layers (e.g., layers including ONON and silicon oxide+ silicon nitride), according to an embodiment. As shown in FIG. 4, similar to FIG. 3, oxide/nitride layers (labeled ONON in FIG. 4) assume a negative bow from about 25° C. to about 400-450° C., crossing from negative to positive values of bowing at about 450° C. Also indicated in FIG. 4 is wafer bowing brought about by SiO₂ and SiN. As previously described herein, by adjusting relative thicknesses of SiO₂ and SiN layers, as well as controlling a number of SiO₂ and SiN layers, wafer bowing may be controlled.

Thus, in the instance of FIG. 4, if oxide/nitride (ONON) present on an active side of a semiconductor wafer is combined with a proper number of SiO₂ and SiN layers at the back side of the wafer, bowing of the semiconductor wafer can be controlled. Accordingly, as is also shown in FIG. 4, when (ONON) is combined with various layers of SiO₂ and SiN(SiO₂+SiN in FIG. 4) the contributions of active side and back side layers sum to a nominal value, that approaches 0. In particular implementations, some amount of bowing of a semiconductor wafer may be tolerable, such as a bowing of, for example, 10 μm, 20 μm, 30 μm, 40 μm, 50 μm, 60 μm, 70 μm, 80 μm, 90 μm, 100 μm, or more. If bowing of a semiconductor wafer remains below one of the aforementioned tolerances, subsequent semiconductor processes, such as photolithography, die singulation, or the like, may be unaffected.

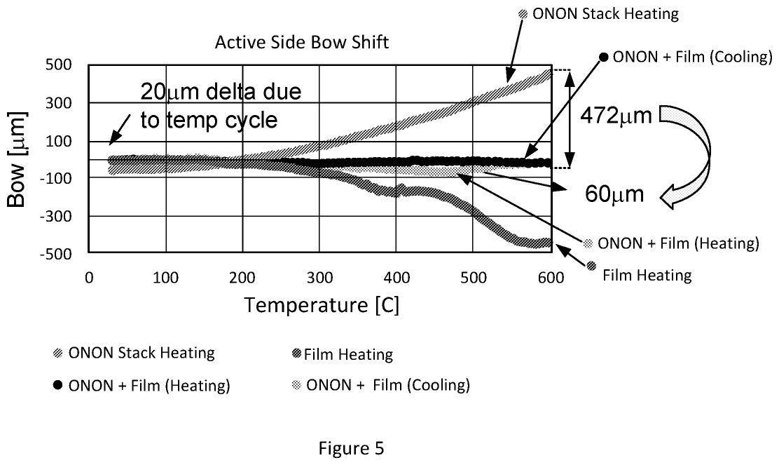

FIG. 5 is a diagram showing a shift in the bowing of an active side of a semiconductor wafer responsive to various layer types, according to an embodiment. In FIG. 5, similar to the profile of FIGS. 3 and 4, a semiconductor substrate comprising layers of ONON exhibit monotonically increasing bowing as temperature increases from about 25° C. to 600° C. FIG. 5 also indicates backside deposited film heating, which corresponds to a back side film produced by way of a processing tool operating to deposit SiO₂ and/or SiN layers at a back side of a semiconductor wafer. Accordingly, the backside deposited film heating profile of FIG. 5 has a shape that generally accords with the shape of FIG. 4 in which bowing increases in the negative sense as a function of increasing temperature.

FIG. 5 additionally includes a profile corresponding to ONON+backside deposited film (Cooling) as well as ONON+backside deposited film (Heating). In the implementation of FIG. 5, these profiles correspond to combined effects of ONON applied to an active side of a semiconductor wafer as well as layers of SiN/SiO₂ applied to a back side of the semiconductor wafer. Thus, as shown, the combined effects of positive (e.g., concave) bowing of brought about by ONON deposited at an active side of a semiconductor substrate combined with negative (e.g., convex) bowing brought about by SiN/SiO₂ applied to a back side of a semiconductor wafer results in only nominal bowing of a semiconductor wafer. As noted in FIG. 5, for this example, bowing due, at least in part, to hysteresis of a semiconductor wafer may be limited to values of about 20 μm. However, in other embodiments, bowing due to hysteresis may be limited to different threshold values, such as values below 30 μm, 40 μm, 50 μm, 60 μm, 70 μm, 80 μm, 90 μm, or 100 μm.

It may be appreciated that in accordance with certain embodiments described herein, a suite of semiconductor wafers having films of various thicknesses and various numbers of silicon oxide/silicon nitride may be deposited at a back side of the wafer. Such deposition of silicon oxide/silicon nitride may occur prior to processing of an active side of the semiconductor wafer. In accordance with a desired application, which may entail that certain processes be applied to an active side of the semiconductor wafer, a wafer having a particular composition at the back side may be selected for processing. Thus, during (and after) processing of the wafer active side, wafer bowing may be maintained within a predetermined tolerance.

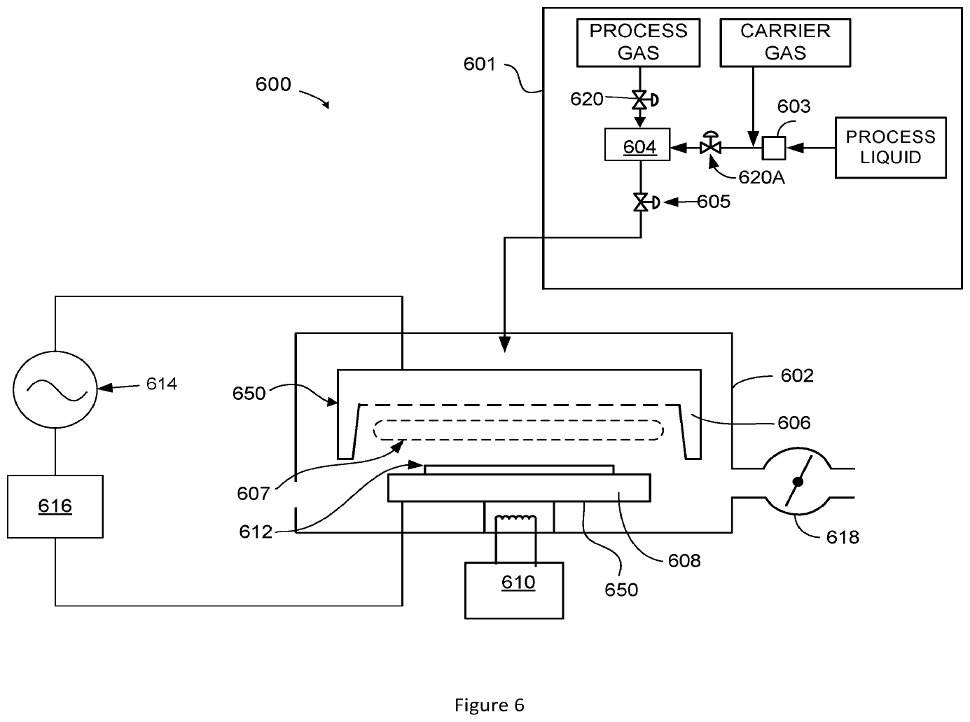

FIG. 6 shows a substrate processing apparatus for depositing films on semiconductor substrates using any number of processes. The apparatus 600 of FIG. 6 utilizes single processing station 602 of a process chamber with a single substrate holder 608 (e.g., a pedestal) in an interior volume which may be maintained under vacuum by vacuum pump 618. Also fluidically coupled to the process chamber for the delivery of (for example) film precursors, carrier and/or purge and/or process gases, secondary reactants, etc. is gas delivery system 601 and showerhead 606. Equipment for generating plasma within the process chamber is also shown in FIG. 6. The apparatus schematically illustrated in FIG. 6 may be adapted for performing, in particular, plasma-enhanced CVD.

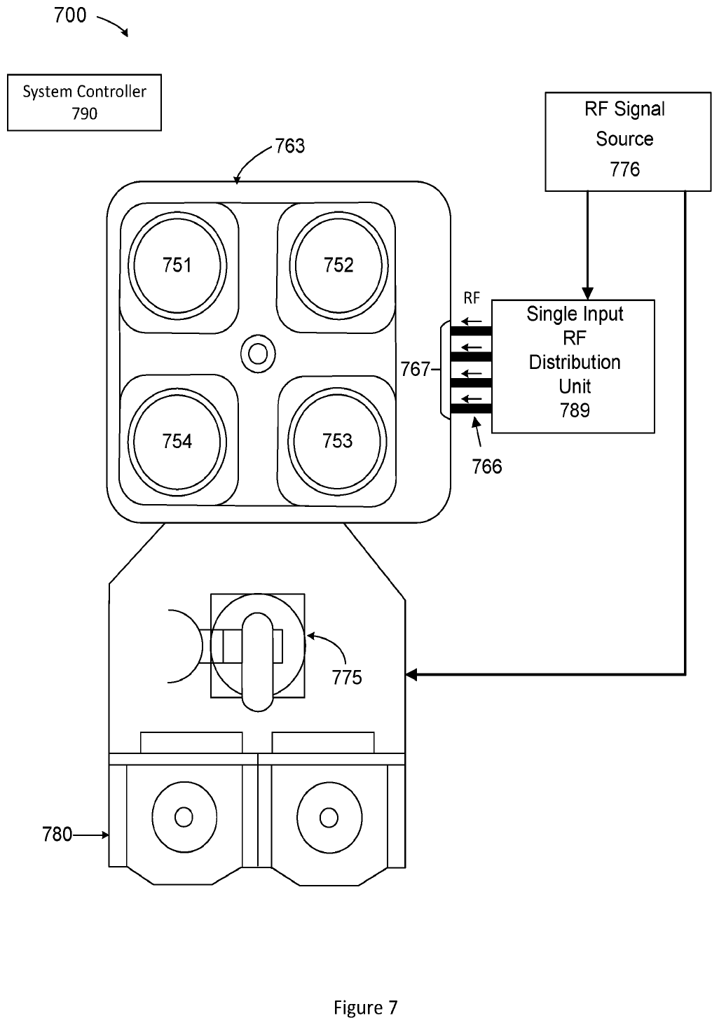

For simplicity, processing apparatus 600 is depicted as a standalone process station (602) of a process chamber for maintaining a low-pressure environment. However, it will be appreciated that a plurality of process stations may be included in a common process tool environment—e.g., within a common reaction chamber—as described herein. For example, FIG. 7 (described herein) depicts an implementation of a multi-station processing tool and is discussed in further detail below. Further, it will be appreciated that, in some implementations, one or more hardware parameters of processing apparatus 600, including those discussed in detail herein, may be adjusted programmatically by one or more system controllers.

Station 602 has electrodes 650. Station 602 of the process chamber fluidically communicates with gas delivery system 601 for delivering process gases, which may include liquids and/or gases, to a distribution showerhead 606. Gas delivery system 601 includes a mixing vessel 604 for blending and/or conditioning process gases for delivery to showerhead 606. One or more mixing vessel inlet valves 620 may control introduction of process gases to mixing vessel 604.

Some reactants may be stored in liquid form prior to vaporization and subsequent delivery to station 602 of a process chamber. The implementation of FIG. 6 includes a vaporization point 603 for vaporizing liquid reactant to be supplied to mixing vessel 604. In some implementations, vaporization point 603 may be a heated liquid injection module. In some other implementations, vaporization point 603 may be a heated vaporizer. In yet other implementations, vaporization point 603 may be eliminated from the process station. In some implementations, a liquid flow controller (LFC) upstream of vaporization point 603 may be provided for controlling a mass flow of liquid for vaporization and delivery to processing station 602.

Showerhead 606 distributes process gases and/or reactants (e.g., film precursors) toward substrate 612 at the process station, the flow of which is controlled by one or more valves upstream from the showerhead (e.g., valves 620, 620A, 605). In the implementation shown in FIG. 6, substrate 612 is located beneath showerhead 606, and is shown resting on a pedestal 608. Showerhead 606 may have any suitable shape, and may have any suitable number and arrangement of ports for distributing process gases to substrate 612. In some implementations with two or more stations, gas delivery system 601 includes valves or other flow control structures upstream from the showerhead, which can independently control the flow of process gases and/or reactants to each station such that gas may be flowed to one station but not another. Furthermore, gas delivery system 601 may be configured to independently control the process gases and/or reactants delivered to each station in a multi-station apparatus such that the gas composition provided to different stations is different; e.g., the partial pressure of a gas component may vary between stations at the same time.

A volume 607 is located beneath showerhead 606. In some implementations, pedestal 608 may be raised or lowered to expose substrate 612 to volume 607 and/or to vary a volume of volume 607. Optionally, pedestal 608 may be lowered and/or raised during portions of the deposition process to modulate process pressure, reactant concentration, etc., within volume 607.

In FIG. 6, showerhead 606 and pedestal 608 are electrically coupled to radio frequency power supply 614 and matching network 616 for powering a plasma generator. In some implementations, the plasma energy may be controlled (e.g., via a system controller having appropriate machine-readable instructions and/or control logic) by controlling one or more of a process station pressure, a gas concentration, a source of RF power, and so forth. For example, radio frequency power supply 614 and matching network 616 may be operated at any suitable power to form plasma having a desired composition of radical species. Likewise, RF power supply 614 may provide RF power of any suitable frequency, or group of frequencies, and power.

In some implementations, the plasma ignition and maintenance conditions are controlled with appropriate hardware and/or appropriate machine-readable instructions in a system controller which may provide control instructions via a sequence of input/output control (IOC) instructions. In one example, the instructions for setting plasma conditions for plasma ignition or maintenance are provided in the form of a plasma activation recipe of a process recipe. In some cases, process recipes may be sequentially arranged, so that all instructions for a process are executed concurrently with that process. In some implementations, instructions for setting one or more plasma parameters may be included in a recipe preceding a plasma process. For example, a first recipe may include instructions for setting a flow rate of an inert (e.g., helium) and/or a reactant gas, instructions for setting a plasma generator to a power set point, and time delay instructions for the first recipe. A second, subsequent recipe may include instructions for enabling the plasma generator and time delay instructions for the second recipe. A third recipe may include instructions for disabling the plasma generator and time delay instructions for the third recipe. It will be appreciated that these recipes may be further subdivided and/or iterated in any suitable way within the scope of the present disclosure.

In some deposition processes, plasma strikes last on the order of a few seconds or more in duration. In certain implementations described herein, much shorter plasma strikes may be applied during a processing cycle. These may be on the order of less than 50 milliseconds, with 25 milliseconds being a specific example.

For simplicity, processing apparatus 600 is depicted in FIG. 6 as a standalone station (602) of a process chamber for maintaining a low-pressure environment. However, it may be appreciated that a plurality of process stations may be included in a multi-station processing tool environment, such as shown in FIG. 7, which depicts a schematic view of an embodiment of a multi-station processing tool.

Processing apparatus 700 employs an integrated circuit fabrication chamber 763 that includes multiple fabrication process stations, each of which may be used to perform processing operations on a substrate held in a wafer holder, such as pedestal 608 of FIG. 6, at a particular process station. In the embodiment of FIG. 7, the integrated circuit fabrication chamber 763 is shown having four process stations, 751, 752, 753, and 754, as well as four cables 766, which provide RF power to each of the four process stations through input ports 767. Other similar multi-station processing apparatuses may have more or fewer process stations depending on the implementation and, for example, a desired level of parallel wafer processing, size/space constraints, cost constraints, etc. Also shown in FIG. 7 is substrate handler robot 775, which may operate under the control of system controller 790, configured to move substrates from a wafer cassette (not shown in FIG. 7) from loading port 780 and into integrated circuit fabrication chamber 763, and onto one of process stations 751, 752, 753, and 754.

FIG. 7 also depicts an embodiment of a system controller 790 employed to control process conditions and hardware states of processing apparatus 700. System controller 790 may include one or more memory devices, one or more mass storage devices, and one or more processors. The one or more processors may include a central processing unit, analog and/or digital input/output connections, stepper motor controller boards, etc. In some embodiments, system controller 790 controls all of the activities of processing tool 700. System controller 790 executes system control software stored in a mass storage device, which may be loaded into a memory device, and executed on a hardware processor of the system controller. Software to be executed by a processor of system controller 790 may include instructions for controlling the timing, mixture of gases, fabrication chamber and/or station pressure, fabrication chamber and/or station temperature, wafer temperature, substrate pedestal, chuck and/or susceptor position, number of cycles performed on one or more substrates, and other parameters of a particular process performed by processing tool 700. These programed processes may include various types of processes including, but not limited to, processes related to determining an amount of accumulation on a surface of the chamber interior, processes related to deposition of film on substrates including numbers of cycles, and processes related to cleaning the chamber. System control software, which may be executed by one or more processors of system controller 790, may be configured in any suitable way. For example, various process tool component subroutines or control objects may be written to control operation of the process tool components necessary to carry out various tool processes.

In some embodiments, software for execution by way of a processor of system controller 790 may include input/output control (IOC) sequencing instructions for controlling the various parameters described above. For example, each phase of deposition and deposition cycling of a substrate may include one or more instructions for execution by system controller 790. The instructions for setting process conditions for an ALD/CFD deposition process phase may be included in a corresponding ALD/CFD deposition recipe phase. In some embodiments, the recipe phases may be sequentially arranged, so that all instructions for a process phase are executed concurrently with that process phase.

Other computer software and/or programs stored on a mass storage device of system controller 790 and/or a memory device accessible to system controller 790 may be employed in some embodiments. Examples of programs or sections of programs for this purpose include a substrate positioning program, a process gas control program, a pressure control program, a heater control program, and a plasma control program. A substrate positioning program may include program code for process tool components that are used to load the substrate onto pedestal 608 (of FIG. 6) and to control the spacing between the substrate and other parts of processing apparatus 700. A positioning program may include instructions for appropriately moving substrates in and out of the reaction chamber as necessary to deposit films on substrates and clean the chamber.

A process gas control program may include code for controlling gas composition and flow rates and optionally for flowing gas into one or more process stations prior to deposition in order to stabilize the pressure in the process station. In some embodiments, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in the exhaust system of the process station, a gas flow into the process station, etc. The pressure control program may include instructions for maintaining the same pressure during the deposition of differing number of cycles on one or more substrates during the processing of the batch.

A heater control program may include code for controlling the current to heating unit 610 (of FIG. 6) that is used to heat the substrate. Alternatively, the heater control program may control delivery of a heat transfer gas (such as helium) to the substrate.

In some embodiments, there may be a user interface associated with system controller 790. The user interface may include a display screen, graphical software displays of the apparatus and/or process conditions, and user input devices such as pointing devices, keyboards, touch screens, microphones, etc.

In some embodiments, parameters adjusted by system controller 790 may relate to process conditions. Non-limiting examples include process gas composition and flow rates, temperature, pressure, plasma conditions, etc. These parameters may be provided to the user in the form of a recipe, which may be entered utilizing the user interface. The recipe for an entire batch of substrates may include compensated cycle counts for one or more substrates within the batch in order to account for thickness trending over the course of processing the batch.

Signals for monitoring the process may be provided by analog and/or digital input connections of system controller 790 from various process tool sensors. The signals for controlling the process may be output by way of the analog and/or digital output connections of processing tool 700. Non-limiting examples of process tool sensors that may be monitored include mass flow controllers, pressure sensors (such as manometers), thermocouples, etc. Sensors may also be included and used to monitor and determine the accumulation on one or more surfaces of the interior of the chamber and/or the thickness of a material layer on a substrate in the chamber. Appropriately programmed feedback and control algorithms may be used with data from these sensors to maintain process conditions.

System controller 790 may provide program instructions for implementing the above-described deposition processes. The program instructions may control a variety of process parameters, such as DC power level, pressure, temperature, number of cycles for a substrate, amount of accumulation on at least one surface of the chamber interior, etc. The instructions may control the parameters to operate in-situ deposition of film stacks according to various embodiments described herein.

For example, the system controller may include control logic for performing the techniques described herein, such as determining an amount of accumulated deposition material currently on at least an interior region of the deposition chamber interior, applying the determine the amount of deposited material, or a parameter derived therefrom, to a relationship between (i) a number of ALD cycles required to achieve a target deposition thickness, and (ii) a variable representing an amount of accumulated deposition material, in order to obtain a compensated number of ALD cycles for producing the target deposition thickness given the amount of accumulated deposition material currently on the interior region of the deposition chamber interior, and performing the compensated number of ALD cycles on one or more substrates in the batch of substrates. The system may also include control logic for determining that the accumulation in the chamber has reached an accumulation limit and stopping the processing of the batch of substrates in response to that determination, and for causing a cleaning of the chamber interior.

In addition to the above-identified functions and/or operations performed by system controller 790 of FIG. 7, the controller may additionally control and/or manage the operations of RF subsystem 789, which may generate RF power (e.g., from a RF signal source 776) and convey RF power to integrated circuit fabrication chamber 763 via radio frequency input ports 767. As described further herein, such operations may relate to, for example, determining upper and lower thresholds for RF power to be delivered to integrated circuit fabrication chamber 763, determining actual (such as real-time) levels of RF power delivered to integrated circuit fabrication chamber 763, RF power activation/deactivation times, RF power on/off duration, operating frequency, and so forth.

In particular embodiments, integrated circuit fabrication chamber 763 may comprise input ports in addition to input port 767 (additional input ports not shown in FIG. 7). Accordingly, integrated circuit fabrication chamber 763 may utilize 8 RF input ports. In particular embodiments, process stations 751-754 of integrated circuit fabrication chamber 665 may each utilize first and second input ports in which a first input port may convey a signal having a first frequency and in which a second input port may convey a signal having a second frequency. Use of dual frequencies may bring about enhanced plasma characteristics, which may give rise to deposition rates within particular limits and/or more easily controlled deposition rates. Dual frequencies may bring about other desirable consequences, and claimed subject matter is not limited in this respect. In certain embodiments, frequencies of between about 300 kHz and about 65 MHz may be utilized. In some implementations, signal frequencies of about 2 MHz or less may be referred to as low frequency (LF) while frequencies greater than about 2 MHz may be referred to as high frequency (HF).

In the foregoing detailed description, numerous specific details are set forth to provide a thorough understanding of the presented embodiments or implementations. The disclosed embodiments or implementations may be practiced without some or all of these specific details. In other instances, well-known process operations have not been described in detail so as to not unnecessarily obscure the disclosed embodiments or implementations. While the disclosed embodiments or implementations are described in conjunction with the specific embodiments or implementations, it will be understood that such description is not intended to limit the disclosed embodiments or implementations.

The foregoing detailed description is directed to certain embodiments or implementations for the purposes of describing the disclosed aspects. However, the teachings herein can be applied and implemented in a multitude of different ways. In the foregoing detailed description, references are made to the accompanying drawings. Although the disclosed embodiments or implementation are described in sufficient detail to enable one skilled in the art to practice the embodiments or implementation, it is to be understood that these examples are not limiting; other embodiments or implementation may be used and changes may be made to the disclosed embodiments or implementation without departing from their spirit and scope. Additionally, it should be understood that the conjunction “or” is intended herein in the inclusive sense where appropriate unless otherwise indicated; for example, the phrase “A, B, or C” is intended to include the possibilities of “A,” “B,” “C,” “A and B,” “B and C,” “A and C,” and “A, B, and C.”

Unless the context of this disclosure clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also generally include the plural or singular number respectively. When the word “or” is used in reference to a list of two or more items, that word covers all of the following interpretations of the word: any of the items in the list, all of the items in the list, and any combination of the items in the list. The term “implementation” refers to implementations of techniques and methods described herein, as well as to physical objects that embody the structures and/or incorporate the techniques and/or methods described herein.

1. A method of performing a process on a wafer, comprising:
(a) determining how wafer bow changes with temperature, wherein the wafer bow is at least partially caused by one or more processes performed on a front side of a wafer;
(b) using information about how the determined wafer bow changes with temperature to determine properties of a back side treatment of wafers, which back side treatment counteracts the wafer bow;
(c) applying the back side treatment identified in (b) to an incoming wafer; and
(d) performing the one or more processes on the front side of the incoming wafer, whereby the back side treatment applied in (c) at least partially prevents the incoming wafer from bowing in response to the one or more processes.

2. The method of claim 1, wherein the one or more processes performed on the front side of the wafer comprises a deposition process.

3. The method of claim 1, wherein the one or more processes performed on the front side of the wafer comprises multilayer stack deposition.

4. The method of claim 1, wherein the one or more processes performed on the front side of the wafer comprises oxide/nitride (ONON) deposition.

5. The method of claim 1, wherein the one or more processes performed on the front side of the wafer comprises an etching process.

6. The method of claim 1, wherein determining how wafer bow changes with temperature comprises measuring wafer bow of a test wafer at multiple different temperatures while the temperature of the test wafer increases.

7. The method of claim 1, wherein determining how wafer bow changes with temperature comprises measuring wafer bow of a test wafer at multiple different temperatures while the temperature of the test wafer decreases.

8. The method of claim 1, wherein determining how wafer bow changes with temperature comprises determining a hysteresis of wafer bow in response to at least one cycle of increasing temperature and decreasing temperature.

9. The method of claim 1, wherein determining how wafer bow changes with temperature comprises measuring wafer bow of a test wafer at multiple different temperatures within a range of temperatures experienced by the incoming wafer during the one or more processes on the front side of the incoming wafer.

10. The method of claim 1, wherein the back side treatment comprises applying one or more layers to the back side of the incoming wafer.

11. The method of claim 1, wherein using the information about how the determined wafer bow changes with temperature to determine properties of a back side treatment of the wafer comprises obtaining temperature versus bow information for test wafers having one or more deposited layers on the back sides of the test wafers.

12. The method of claim 11, wherein a first test wafer has a layer of a first material on its back side and a second test wafer has a deposited layer of a second material on its back side.

13. The method of claim 12, wherein using the information about how the determined wafer bow changes with temperature to determine properties of a back side treatment of the wafer further comprises determining a back side treatment that includes:
depositing a first layer of the first material to a first thickness on the wafer's back side, and
depositing a second layer of the second material to a second thickness on the wafer's back side.

14. An apparatus for controlling wafer bow during integrated circuit processing, comprising:
one or more process stations of a multi-station fabrication chamber,
the one or more process stations being configured to receive a corresponding number of semiconductor wafers having undergone a fabrication process at a back side of each wafer,
the one or more process stations being additionally configured to perform a fabrication process to an active side of each wafer,
the one or more process stations being additionally configured to cooperate with each received semiconductor wafer to maintain wafer bow to a value below a threshold level during the fabrication process performed to the active side of each wafer.

15. The apparatus of claim 14, wherein the fabrication process performed to the active side of each wafer involves elevating the temperature of the wafer followed by reducing the temperature of the wafer.

16. The apparatus of claim 14, wherein the fabrication process performed to the active side of each wafer comprises material deposition.

17. The apparatus of claim 14, wherein the fabrication process performed to the active side of each wafer comprises removal of material from the wafer.

18. The apparatus of claim 14, wherein the threshold level corresponds to about 100 μm and wherein each wafer has a diameter of about 300 mm.

19. The apparatus of claim 14, wherein the threshold level corresponds to about 75 μm and wherein each wafer has a diameter of about 300 mm.

20. The apparatus of claim 14, wherein the multi-station fabrication chamber comprises 4 process stations.

21. The apparatus of claim 14, wherein the fabrication process at the back side of each wafer comprises depositing silicon oxide and/or silicon nitride layers.

22. A method of controlling wafer bow in an integrated circuit fabrication process, comprising:
characterizing the wafer bow in response to performing one or more active fabrication processes to an active side of an integrated circuit wafer;
determining one or more second fabrication processes, to be applied to a back side of the integrated circuit wafer, to bring the wafer bow to below a predetermined threshold based on the one or more active fabrication processes; and
performing the one or more second fabrication processes on the back side of the integrated circuit wafer.

23. The method of claim 22, wherein the one or more active fabrication processes performed to the active side of the integrated circuit wafer comprises elevating the temperature of the integrated circuit wafer.

24. The method of claim 22, wherein the one or more active fabrication processes performed to the active side of the integrated circuit wafer comprises depositing a material on the active side of the integrated circuit wafer.

25. The method of claim 24, wherein the material deposited on the active side of the integrated circuit wafer comprises silicon nitride.

26. The method of claim 24, wherein the material deposited on the active side of the integrated circuit wafer comprises silicon oxide.

27. The method of claim 22, wherein the one or more active fabrication processes performed to the active side of the integrated circuit wafer comprises removing a material from the active side of the integrated circuit wafer.

28. The method of claim 22, wherein performing the one or more second fabrication processes on the back side of the integrated circuit wafer results in decreasing the wafer bow to an amount below 100 μm when the wafer has a diameter of about 300 mm.

29. The method of claim 22, wherein performing the one or more second fabrication processes on the back side of the integrated circuit wafer results in decreasing the wafer bow to an amount below about 75 μm when the wafer has a diameter of about 300 mm.

30. The method of claim 22, wherein performing the one or more second fabrication processes on the back side of the integrated circuit wafer comprises depositing a silicon oxide layer, a silicon nitride layer, or both a silicon oxide and a silicon nitride layer at the back side.
